(19) United States
(12) Patent Application Publication
(10) Pub. No.: US 2026/0011561 A1
(43) Pub. Date: Jan. 8, 2026

(54) SURFACE PROCESSING METHOD AND METHOD OF MANUFACTURING SEMICONDUCTOR DEVICE

(71) Applicant: FUJI ELECTRIC CO., LTD., Kawasaki-shi (JP)

(72) Inventor: Tomo ODASHIMA, Matsumoto-city (JP)

(73) Assignee: FUJI ELECTRIC CO., LTD., Kawasaki-shi (JP)

(21) Appl. No.: 19/223,562

(22) Filed: May 30, 2025

(30) Foreign Application Priority Data
Jul. 5, 2024 (JP) 2024-109181

(51) Int. Cl. H01L 21/288; C23C 18/32; H01L 21/304

(52) U.S. Cl. CPC H01L 21/288; C23C 18/32; H01L 21/304

(57) ABSTRACT

A surface processing method for forming a plating film on a metal layer in manufacturing a semiconductor device. The method includes: as a first precipitation process, immersing the metal layer in a first solution containing a second metal that is more noble than a first metal of the metal layer, to thereby precipitate a metal film containing the second metal on the metal layer; and as a second precipitation process, performing an electroless plating treatment to replace the second metal in the metal film with a third metal contained in a second solution and to precipitate the plating film containing the third metal on the metal layer. The metal layer includes a first portion and a second portion mutually exclusive of each other. In the first precipitation process, a concentration of the first solution is lower at a surface of the second portion than at that of the first portion.

### CROSS REFERENCE TO RELATED APPLICATIONS

This application is based upon and claims the benefit of priority of the prior Japanese Patent Application No. 2024-109181, filed on Jul. 5, 2024, the entire contents of which are incorporated herein by reference.

### BACKGROUND OF THE INVENTION

### 1. Field of the Invention

Embodiments of the disclosure relate to a surface processing method and a method of manufacturing a semiconductor device.

### 2. Description of the Related Art

Japanese Laid-Open Patent Publication No. 2010-121151 and Japanese Laid-Open Patent Publication No. 2023-184437 describe a technique of performing etching using an acid bath solution or an alkaline bath solution before a zincate treatment as a pre-treatment of electroless plating performed on the surface of an electrode mainly containing aluminum (Al). Japanese Laid-Open Patent Publication No. 2010-121151 describes a technique of performing desmutting treatment after etching but before the zincate treatment to remove smut generated on the electrode surface during etching.

### SUMMARY OF THE INVENTION

According to an embodiment of the present disclosure, a surface processing method for forming a plating film on a surface of a metal layer in manufacturing a semiconductor device, the metal layer containing a first metal, the method includes: as a first precipitation process, immersing the metal layer in a first solution containing a second metal that is more noble than the first metal, to thereby precipitate a metal film containing the second metal on the surface of the metal layer; and as a second precipitation process, performing an electroless plating treatment using a second solution, to replace the second metal in the metal film with a third metal contained in the second solution and to precipitate the plating film containing the third metal on the surface of the metal layer. The metal layer includes a first portion and a second portion mutually exclusive of each other. In the first precipitation process, a concentration of the first solution is lower at a surface of the second portion than at a surface of the first portion.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a flowchart depicting an outline of a method of manufacturing a semiconductor device according to a first embodiment.

FIG. 2 is a flowchart depicting an outline of a surface processing method according to the first embodiment.

FIG. 3 is a plan view depicting a layout of a semiconductor wafer during manufacturing of the semiconductor device according to the first embodiment, as viewed from a front surface thereof.

FIG. 4 is an enlarged plan view depicting a chip region in FIG. 3.

FIG. 5 is an enlarged plan view depicting another example of the chip region in FIG. 3.

FIG. 6 is a cross-sectional view schematically depicting a state of the semiconductor device according to the first embodiment during manufacturing.

FIG. 7 is a cross-sectional view schematically depicting a state of the semiconductor device according to the first embodiment during manufacturing.

FIG. 8 is a cross-sectional view schematically depicting a state of the semiconductor device according to the first embodiment during manufacturing.

FIG. 9 is a cross-sectional view schematically depicting a state of the semiconductor device according to the first embodiment during manufacturing.

FIG. 10 is a cross-sectional view schematically depicting a state of the semiconductor device according to the first embodiment during manufacturing.

FIG. 11 is a cross-sectional view schematically depicting a state of the semiconductor device according to the first embodiment during manufacturing.

FIG. 12 is a cross-sectional view schematically depicting a state of a semiconductor device according to the second embodiment during manufacture.

FIG. 13 is a cross-sectional view schematically depicting a state of the semiconductor device according to the second embodiment during manufacture.

FIG. 14 is a cross-sectional view schematically depicting a state of the semiconductor device according to the second embodiment during manufacture.

FIG. 15 is a cross-sectional view schematically depicting a state of the semiconductor device according to the second embodiment during manufacture.

FIG. 16 is a cross-sectional view depicting results of observing a state of a surface of a front electrode (main electrode) in a verification example.

FIG. 17 is a cross-sectional view depicting results of observing a state of a surface of a front electrode (dummy electrode) in the verification example.

### DETAILED DESCRIPTION OF THE INVENTION

In Japanese Laid-Open Patent Publication No. 2010-121151 and Japanese Laid-Open Patent Publication No. 2023-184437, during the zincate treatment, the electrode containing Al as a main component may be excessively eluted, and the adhesion between the electrode and the plating film may be reduced.

An outline of an embodiment of the present disclosure is described. (1) A surface processing method according to one aspect of the present disclosure is a surface processing method for forming a plating film on a surface of a metal layer containing a first metal and is as follows. A first precipitation process of immersing the metal layer in a solution containing a second metal that is more noble than the first metal contained in the metal layer, thereby, precipitating a metal film containing the second metal on the surface of the metal layer is performed. A second precipitation process of performing an electroless plating treatment replacing the second metal in the metal film with a third metal contained in a plating solution and precipitating the plating film containing the third metal on the surface of the metal layer is performed. The metal layer includes a first portion and a second portion mutually exclusive of each other and in the first precipitation process, a concentration of the solution is made lower at the surface of the second portion than at the surface of the first portion.

According to the above disclosure, dissolution of the second portion of the metal layer is facilitated and dissolution of the first portion of the metal layer is suppressed, whereby adhesion between the first portion of the metal layer and the plating film can be improved, thereby improving reliability.

(2) Further, the surface processing method according to the present disclosure, in (1) above, includes retaining a liquid on the surface of the second portion of the metal layer before the first precipitation process, the liquid being water or a low-concentration solution having a lower concentration of the second metal than the solution; and the first precipitation process may include diluting the solution at the surface of the second portion of the metal layer with the liquid.

According to the above disclosure, application to existing manufacturing processes is easy.

(3) Further, in the surface processing method according to the present disclosure, in (2) above, the retaining may include: forming, on the surface of the metal layer, a convex portion containing an insulating material and surrounding the surface of the second portion, and retaining the liquid in a recess surrounded by the convex portion, thereby, retaining the liquid on the surface of the second portion of the metal layer.

According to the above disclosure, application to existing manufacturing processes is easy.

(4) Further, in the surface processing method according to the present disclosure, in (2) above, the retaining may include forming, on the surface of the metal layer, a hydrogel layer covering the surface of the second portion, the hydrogel layer absorbing the liquid, thereby, retaining the liquid on the surface of the second portion of the metal layer.

According to the above disclosure, application to existing manufacturing processes is easy.

(5) Further, in the surface processing method according to the present disclosure, in any one of (1) to (4) above, the first metal may be aluminum, the solution may be a zincate solution containing zinc as the second metal, and the third metal may be nickel.

According to the above disclosure, application to a general zincate treatment to improve adhesion of a nickel plating film by electroless nickel plating treatment is possible.

(6) A method of manufacturing a semiconductor device according to one aspect of the present disclosure is a method of manufacturing a semiconductor device having the metal layer whose surface is covered with the plating film formed by the surface processing method above, the method of manufacturing a semiconductor device being as follows. Before the first precipitation process, a first process of forming an element structure of a predetermined semiconductor element in a semiconductor substrate, at a main surface of the semiconductor substrate, is performed; and a second process of forming the metal layer on the main surface is performed. In the second process, the first portion of the metal layer constitutes a main electrode electrically connected to the element structure, and the second portion of the metal layer constitutes a dummy electrode not used as the semiconductor element.

According to the above disclosure, a plating film with high adhesion can be formed on the surface of the main electrode, thereby improving reliability of the semiconductor device.

Findings underlying the present disclosure are discussed. During mounting a semiconductor chip (semiconductor device), a metal wiring member is soldered to a surface electrode of the semiconductor chip by solder bumps or the like. Generally, a surface electrode on a front surface of a semiconductor chip is formed of aluminum (Al) or an Al alloy, but Al has poor solder wettability and low adhesion to solder. Therefore, before soldering to another member, a metal plating film with high adhesion to solder, such as nickel (Ni), is formed by a plating treatment on the surface of a surface electrode (hereinafter referred to as an Al electrode) that mainly contains Al.

Electroless plating is known as a plating method for semiconductor wafers. Electroless plating is a method in which metal ions (e.g., Ni ions) in a plating solution are reduced by a chemical reaction with a substance (e.g., a reducing agent such as hypophosphorous acid) in the plating solution to precipitate as a metal on the surface of the plated material (here, an Al electrode). Since electroless plating can be performed without passing electricity through the plated material, the Al electrodes of all the semiconductor devices fabricated on the same semiconductor wafer can be simultaneously plated.

Al is an active metal and is easily oxidized, thereby forming a chemically stable aluminum oxide (Al₂O₃) film (hereinafter, referred to as an Al oxide film) on the surface of the Al electrode during or before the electroless plating. If electroless plating is performed directly on the surface of the Al electrode in this state, the adhesion between the Al electrode and the plating film is reduced. Therefore, a method has been proposed in which a zincate treatment is performed on the surface of the Al electrode as a pre-treatment for the electroless plating on the surface of the Al electrode to improve the adhesion of the plating film.

In the zincate treatment, in conjunction with dissolution of the Al oxide film on the surface of the Al electrode using a zincate solution, a Zn film with higher adhesion to Ni than Al is precipitated on the surface of the Al electrode by a substitution reaction between Al in the Al electrode and zinc (Zn) in the zincate solution. By forming the Zn film on the surface of the Al electrode, in conjunction with suppressing oxidation of the surface of the Al electrode, Ni in the plating solution is substituted for Zn in the Zn film during the electroless plating and precipitates on the surface of the Al electrode by an autocatalytic reaction, improving the adhesion between the Al electrode and the Ni plating film.

Usually, in one zincate treatment, a Zn film with a large particle size and poor film quality (large voids) is formed, and adhesive strength of the Ni plating film formed on the surface of the Al electrode following the Zn film is not practical. Therefore, the Zn film formed by the zincate treatment (first) is peeled off with a nitric acid (HNO₃) solution and the zincate treatment (second) is performed again, thereby forming a dense Zn film with a small particle size on the surface of the Al electrode, such treatment is called double zincate treatment. This enables the formation of a Ni plating film with a practical adhesive strength on the surface of the Al electrode.

As another method for forming the dense Zn film on the surface of the Al electrode by the zincate treatment, Japanese Laid-Open Patent Publication No. 2010-121151 and Japanese Laid-Open Patent Publication No. 2023-184437 propose a method in which the surface of the Al electrode is made into a clean state suitable for plating by performing etching using an acid bath solution or an alkaline bath solution or a desmutting treatment using the nitric acid solution before the zincate treatment. Since Al is an amphoteric element (amphoteric metal) which reacts with both acids and bases, Al is dissolved and eroded by both the acid solution and the alkaline solution used in the pre-treatment of the electroless plating.

Since the amount of dissolution or erosion of Al is very small, it does not cause any problem when electroless plating is performed on a general bulk Al material, and conversely, the surface of the Al material is dissolved and moderately roughened to improve the adhesion between the Al material and the plating film. On the other hand, the front electrode (Al electrode) of the semiconductor device is becoming thinner due to increased miniaturization of the semiconductor devices and have a thickness of about 1 μm to 10 μm. Therefore, depending on pre-treatment conditions of the electroless plating, there is a problem in that the thickness of the Al electrode is reduced by half or locally disappears.

In the zincate treatment, Al at the surface of the Al electrode releases electrons (e⁻), which dissolve into the zincate solution, and instead of Al, metal ions (Zn²⁺) in the zincate solution receive the electrons forming a metal element (Zn) and precipitating on the surface of the Al electrode. Therefore, theoretically, when the substitution of Al with Zn in the zincate solution occurs over the entire surface of the Al electrode, the substitution reaction should stop, and the dissolution of the Al electrode should stop. However, in reality, the substitution reaction of Al with Zn does not proceed uniformly over the entire surface of the Al electrode, and the local dissolution of the Al electrode proceeds.

In a portion where the Al electrode dissolves, a long and narrow groove called a spike is generated on the surface of the Al electrode in the depth direction. The spike on the surface of the Al electrode is filled with the plating film having low adhesion to the Al electrode due to autocatalytic reaction of Ni in the plating solution, or the spike becomes a gap between the Al electrode and the plating film. When the sides of multiple spikes generated in a dense manner are connected to each other, the adhesion between the Al electrode and the plating film becomes low at the connection points of the spikes and the plating film peels off from the surface of the Al electrode due to the tensile stress received from the metal wiring member, for example.

The present embodiment provides a surface processing method for the plated material and a method of manufacturing for a semiconductor device that can improve reliability.

Embodiments of a surface processing method and a method of manufacturing a semiconductor device according to the present disclosure are described in detail with reference to the accompanying drawings. In the description of the embodiments below and the accompanying drawings, main portions that are identical are given the same reference numerals and are not repeatedly described.

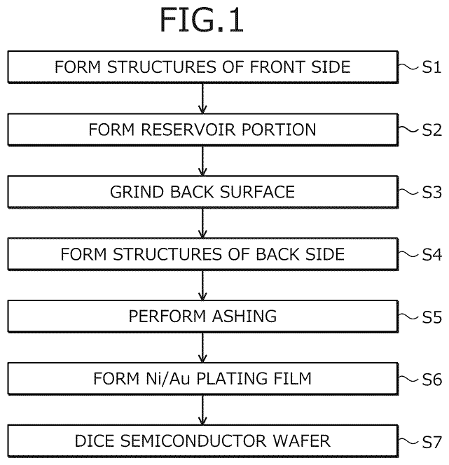

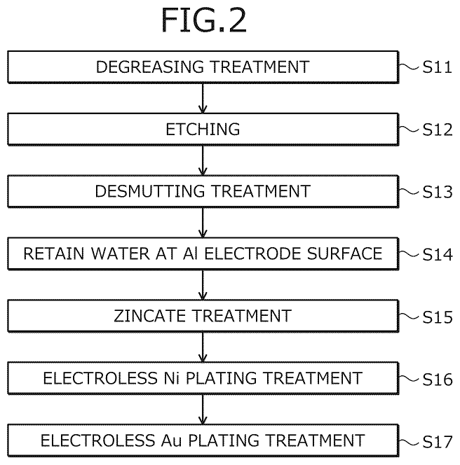

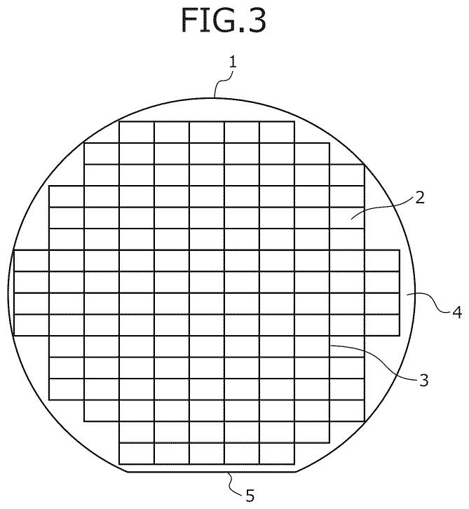

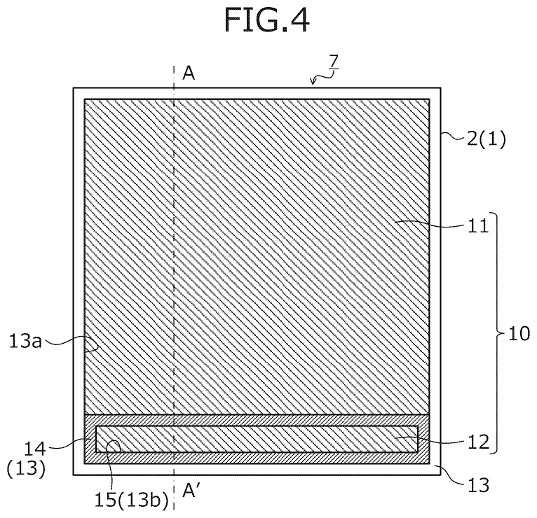

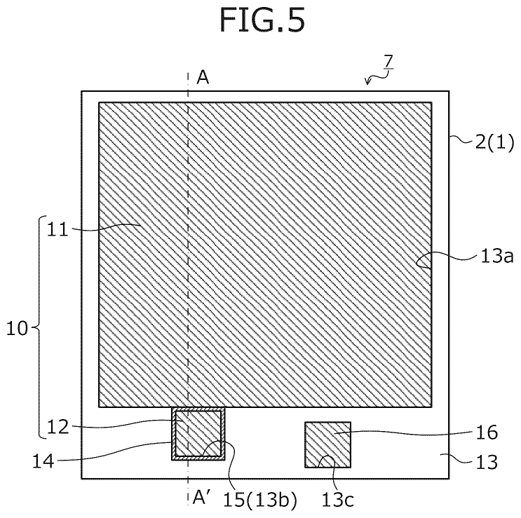

A method of manufacturing a semiconductor device according to a first embodiment solving the above problems and a surface processing method according to the first embodiment are described below. FIG. 1 is a flowchart depicting an outline of the method of manufacturing the semiconductor device according to the first embodiment. FIG. 2 is a flowchart depicting an outline of the surface processing method according to the first embodiment. FIG. 2 depicts an outline of the process at step S6 in FIG. 1. FIG. 3 is a plan view depicting a layout of a semiconductor wafer during manufacturing of the semiconductor device according to the first embodiment, as viewed from a front surface thereof. FIG. 4 is an enlarged plan view depicting a chip region in FIG. 3. FIG. 5 is an enlarged plan view depicting another example of the chip region in FIG. 3. A front electrode 10 and a convex portion 14 are indicated by different hatching in FIGS. 4 and 5.

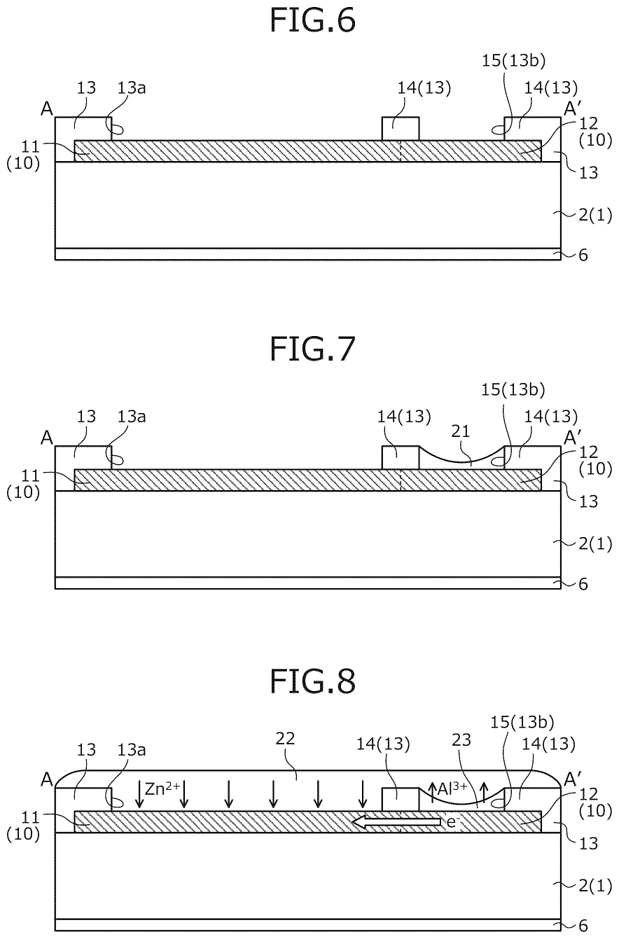

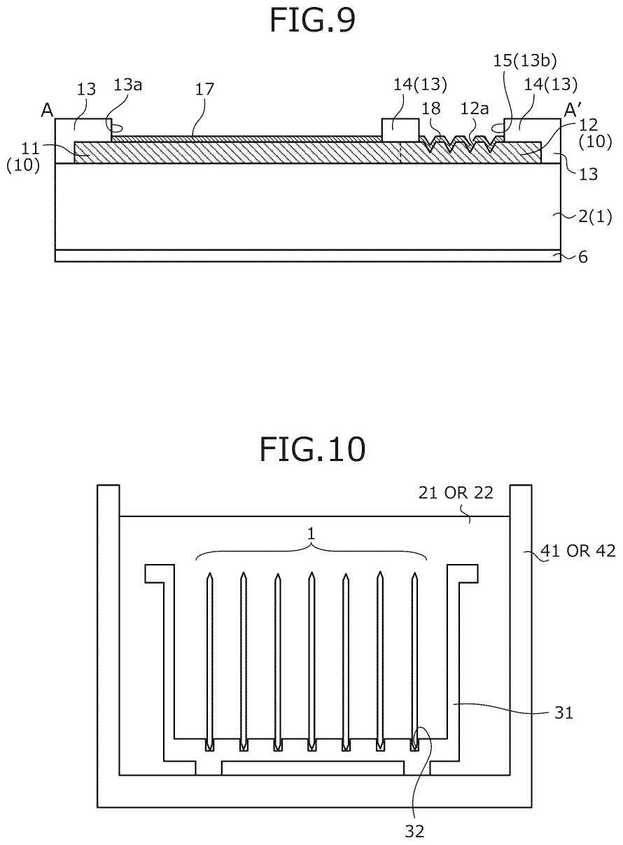

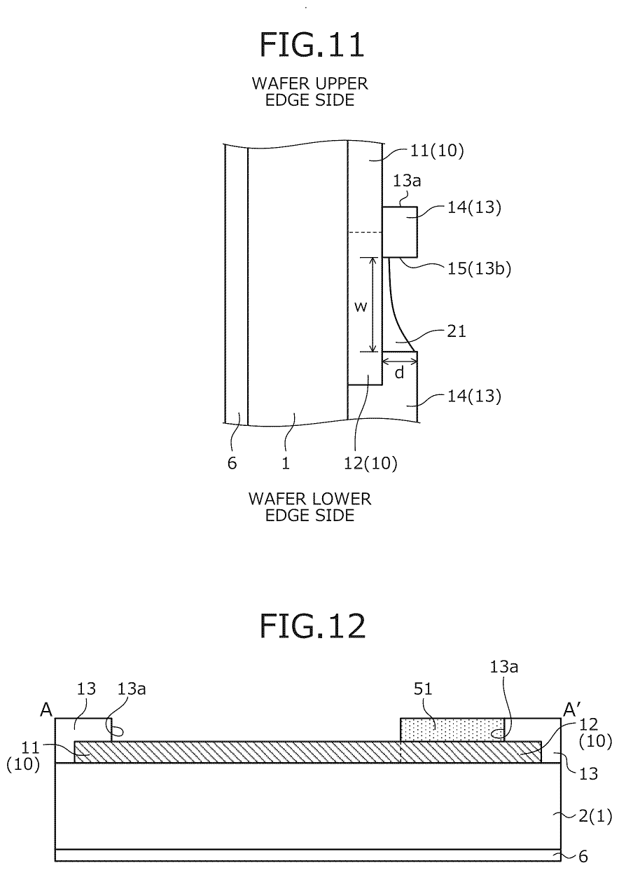

FIGS. 6, 7, 8, 9, 10, and 11 are cross-sectional views that schematically depict states of the semiconductor device according to the first embodiment during manufacturing. FIGS. 6 to 9 are cross-sectional structures taken along a line A-A′ in FIGS. 4 and 5. FIG. 6 depicts a state after the process at step S2 in FIG. 1. FIGS. 7 and 11 depict states after the process at step S14 in FIG. 2. FIG. 11 is an enlarged view of a state of a reservoir portion 15 of the semiconductor wafer 1 pulled out of water 21. FIG. 10 depicts a state in which the semiconductor wafer 1 is immersed in a bath filled with a predetermined liquid (a bath 41 filled with the water 21 in the process at step S14, and a bath 42 filled with a zincate solution 22 in the process at step S15). FIGS. 8 and 9 depict states during and after the process at step S15 in FIG. 2, respectively.

First, structures of a front surface of a semiconductor device 7 are formed in each chip region 2 on a front surface (first main surface) of a semiconductor wafer (semiconductor substrate) 1 (step S1: a first step, a second step), respectively. Multiple chip regions 2 are disposed on the semiconductor wafer 1 (see FIG. 3). The chip regions 2 are portions that are cut from the semiconductor wafer into individual semiconductor chips by dicing the semiconductor wafer 1 along scribe regions (dicing lines) 3. The chip regions 2 have a substantially rectangular shape in a plan view and are arranged adjacent to each other in a matrix. The scribe regions 3 are between the adjacent chip regions 2 and between the chip regions 2 and nonoperating regions 4.

The scribe regions 3 are provided in a lattice shape surrounding periphery of the chip regions 2. The nonoperating regions 4 are portions that are not used as semiconductor chips between an edge (wafer edge) of the semiconductor wafer 1 and a chip region 2 closest to the wafer edge. The nonoperating regions 4 of the semiconductor wafer 1 are portions that are held, for example, by a wafer holder (such as a conveying hand (not depicted) or a slot 32 (see FIG. 10) of a wafer cassette 31) of a conveying jig for the semiconductor wafer 1. The semiconductor wafer 1 may have, for example, an orientation flat (straight notch) 5 or a notch (V-shaped notch, not depicted) which indicates surface orientation. The semiconductor wafer 1 may contain silicon (Si) or silicon carbide (SiC) as material.

A semiconductor device 7 includes a front electrode (hereinafter referred to as a front electrode) 10 on a front surface of the semiconductor chip (an individual chip region 2 cut from the semiconductor wafer) and has a structure in which a surface of a portion of the front electrode 10 (main electrode 11) is covered with a plating film to enhance heat dissipation of the semiconductor chip (see FIGS. 4, 5, and 16). The front electrode 10 of the semiconductor device 7 has a main electrode 11 electrically connected to a front element structure (not depicted) of the semiconductor device 7, and a dummy electrode 12 which does not constitute the semiconductor device 7. The front element structure is formed on the front surface of the semiconductor chip (front surface of the semiconductor wafer 1 in each chip region 2) in an active region. The active region is a region through which a main current flows when the semiconductor device 7 is on.

The active region has, for example, a substantially rectangular shape in a plan view and is disposed in substantially a center (chip center) of the semiconductor chip. Between the active region and an edge of the semiconductor chip (chip edge) is an edge termination region that surrounds a periphery of the active region. The edge termination region has a function of relaxing an electric field of a front side of the semiconductor chip and maintaining a breakdown voltage. In the edge termination region, a general voltage withstanding structure (not depicted) such as a field limiting ring (FLR), a junction termination extension (JTE) structure, or a guard ring is disposed. The breakdown voltage is a limit voltage at which the semiconductor device 7 does not malfunction or break down.

In a case where the semiconductor device 7 is a diode (semiconductor element), the front element structure refers to an anode region. FIG. 4 depicts a layout of an electrode pad (anode pad) in this case. In a case where the semiconductor device 7 is a semiconductor device such as a metal oxide semiconductor field effect transistor (MOSFET) having an insulated gate with a three-layer structure of metal-oxide-semiconductor) or an insulated gate bipolar transistor (IGBT), the front element structure refers to an insulated gate structure. FIG. 5 depicts a layout of electrode pads (source pad or emitter pad, gate pad 16) in this case.

Structures on the front surface of the semiconductor device 7 include the front element structure (element structure), the front electrode 10 (main electrode 11, dummy electrode 12), an insulating layer (interlayer insulating film, or stacked film including a field oxide film and an interlayer insulating film, not depicted), a passivation film 13, and an opening 13a in the passivation film 13 (FIG. 4). In a case where the semiconductor device 7 is a MOSFET or an IGBT, a front structures of the semiconductor device 7 include, in addition to the above-mentioned configuration, the gate pad 16 and a gate finger (not depicted) (FIG. 5). The gate pad 16 and the gate finger are formed on an insulating layer on the front surface of the semiconductor chip. The main electrode 11 and the gate pad 16 are respectively exposed in openings 13a and 13c of the passivation film 13.

The front electrode 10 is a metal layer mainly containing aluminum (Al: first metal) and is, for example, an Al alloy film such as an Al film or an aluminum silicon (Al—Si) film. The main electrode 11 is a portion (first portion) of the front electrode 10 other than a dummy electrode 12 described later. The main electrode 11 has about a same surface area as a surface area of the active region and covers approximately the entire surface of the active region. The main electrode 11 is, for example, a source electrode of the MOSFET, an emitter electrode of the IGBT, or an anode electrode of the diode. The main electrode 11 has unevenness (for example, unevenness due to the interlayer insulating film and a contact hole thereof) corresponding to the front element structure. The portion of the main electrode 11 exposed in the opening 13a of the passivation film 13 described later functions as an electrode pad (source pad, emitter pad, or anode pad).

The dummy electrode 12 is a portion (second portion) of the front electrode 10 and is connected to the main electrode 11 (see FIG. 6). That is, the dummy electrode 12 is formed of a same material as a material of the main electrode 11 and is fixed to a same potential as that of the main electrode 11. The dummy electrode 12 has a function of dissolving instead of the main electrode 11 during later-a described the process at step S15 to thereby suppress dissolution of the main electrode 11. The dummy electrode 12 may be in direct contact with the front surface of the semiconductor wafer 1 or may be formed on an insulating layer on the front surface of the semiconductor wafer 1. The dummy electrode 12 may be disposed in the active region or the edge termination region. The dummy electrode 12 may be disposed in, for example, any of the scribe regions 3 and may be separated from the semiconductor chip during dicing at step S7 described later.

A surface area of the front electrode 10 is a sum of a surface area of the main electrode 11 and a surface area of the dummy electrode 12. The surface area of the main electrode 11 is large enough to obtain a predetermined current capacity of the semiconductor device 7. The surface area of the dummy electrode 12 is smaller than the surface area of the main electrode 11. The gate pad 16 may be formed of a same material as the material of the front electrode 10. The passivation film 13 is a protective film (insulating film) containing an organic insulator such as a polyimide, is formed on a top layer of the front surface of the semiconductor wafer 1 and covers the entire front surface of the semiconductor wafer 1. The passivation film 13 has the openings 13a and 13c that expose electrode pads. An opening exposing the scribe regions 3 may be formed in the passivation film 13.

Thereafter, as depicted in FIGS. 4 to 6, a reservoir portion 15 is formed on a surface of the dummy electrode 12, the reservoir portion 15 being used in the process at step S6 described later (step S2). The reservoir portion 15 has a function of retaining the water (H₂O) 21 on the surface of the dummy electrode 12 in the process at step S14 described later (see FIGS. 2 and 7). The reservoir portion 15 is, for example, a recess formed by a convex portion 14 made of an insulating resin (insulating material) such as a polyimide formed on the surface of the dummy electrode 12, and the surface of the dummy electrode 12 continuous with a side of the convex portion 14. The convex portion 14 covers the periphery of the dummy electrode 12 and surrounds the surface of the dummy electrode 12 in a substantially rectangular shape as viewed from the front surface of the semiconductor wafer 1.

For example, the convex portion 14 may be formed by a portion of the passivation film 13. In this case, the process at step S2 may be performed simultaneously with the formation of the passivation film 13. That is, in conjunction with forming the openings 13a and 13c exposing the electrode pads in the passivation film 13, an opening 13b exposing the dummy electrode 12 is formed. Of the passivation film 13, a portion surrounding the periphery of the opening 13b exposing the dummy electrode 12 constitutes the convex portion 14. The convex portion 14 may cover the main electrode 11 at a boundary between the main electrode 11 and the dummy electrode 12. A recess of the passivation film 13 resulting from the opening 13b constitutes the reservoir portion 15.

Then, the semiconductor wafer 1 is ground (back grinding) from a back surface (second main surface) thereof to be thinned to a product thickness used as the semiconductor device 7 (step S3). Next, structures on the back surface of the semiconductor device 7 are formed (step S4). The structures on a back side of the semiconductor device 7 include a back element structure (not depicted) and a back electrode 6. The back element structure is, for example, a drain region of the MOSFET, a collector region of the IGBT, or a cathode region of the diode. The back element structure is formed at the entire back surface of the semiconductor wafer 1 by ion implantation of a dopant from the back surface of the semiconductor wafer 1 and a heat treatment for electrically activating the dopant.

In a case where the semiconductor wafer 1 is a bulk wafer, both the front and back element structures are formed in the semiconductor wafer 1. In a case where the semiconductor wafer 1 is an epitaxial substrate formed by stacking multiple epitaxial layers on a starting wafer (bulk wafer), the starting wafer constitutes the back element structure and the front element structure is formed in the epitaxial layer. Therefore, in a case where the semiconductor wafer 1 is an epitaxial substrate, the process at step S3 described above is omitted and only the back electrode 6 is formed in the process at step S4.

The back electrode 6 is a surface electrode on the back surface of the semiconductor chip and is electrically connected to the back element structure. The back electrode 6 is formed on the entire back surface of the semiconductor wafer by a general method such as vapor deposition or sputtering. A top surface of the back electrode 6 (a surface to be bonded to a circuit pattern of a circuit board in an assembly process) may be preferably formed of, for example, a gold (Au) film, but may be formed of a same material as that of the front electrode 10. The back electrode 6 is, for example, a drain electrode of the MOSFET, a collector electrode of the IGBT, or a cathode electrode of the diode.

Next, organic residues on the surfaces of metal electrodes exposed in the openings 13a to 13c of the passivation film 13 (namely, surfaces of the main electrode 11, the dummy electrode 12, and the gate pad 16: hereinafter referred to as a surface of an Al electrode) are removed by ashing (ashing treatment) (step S5). Next, a protective tape (not depicted) is applied to a surface of the semiconductor wafer 1, the surface on which the plating film is not to be formed. For example, the protective tape is applied to the back surface of the semiconductor wafer 1 to cover the back electrode 6 with the protective tape and then the protective tape is applied to the periphery of the semiconductor wafer 1 to cover the side of the semiconductor wafer 1 with the protective tape. Thereafter, the semiconductor wafer 1 is inserted into a heat treatment furnace to be heated, improving adhesion between the back and side surfaces of the semiconductor wafer 1 and the protective tape.

Next, the plating film is formed on the surface of the Al electrode exposed in the openings 13a to 13c of the passivation film 13 (step S6). Specifically, as depicted in FIG. 2, the process at step S6 is performed by carrying out five pre-treatment steps (pre-treatment for electroless plating) including a degreasing treatment (step S11), etching (step S12), a desmutting treatment (step S13), retaining water on the Al electrode surface (step S14: retaining process), and a zincate treatment (step S15: first precipitation process) in this order, followed by the electroless plating (second precipitation step) at steps S16 and S17. The reservoir 15 above is required to be formed on the surface of the dummy electrode 12 at any timing before the process at step S14 (preferably before the process at step S6).

The processes from step S11 to step S17 are, for example, successive processes by a general automated plating equipment and are made into a series (line) to be performed under the same conditions (batch processing) on all semiconductor wafers 1 in multiple wafer cassettes 31 (see FIG. 10) passing through the line. Between each processes at step S11 to step S14 and between each processes from step S15 to step S17, water washing and drying treatments (not depicted) are included. The processes from step S11 to step S17 are preferably performed successively with water washing treatment in between at the above-mentioned timing and may be performed without use of an automated plating equipment. The processes from step S11 to step S17 may be single-wafer processing in which semiconductor wafers 1 are processed one by one.

The processes from step S11 to S15 are for making the surface of the Al electrode into a clean state suitable for electroless plating. Specifically, the degreasing (cleaning) treatment at step S11 cleans the Al electrode surface with a surfactant to impart wettability to the Al electrode surface with an etching solution in the process at step S12. In conjunction with dissolving (etching) the Al oxide film on the Al electrode surface with the etching solution, the etching at step S12 adheres metal in the etching solution to the Al electrode surface thereby suppressing excessive dissolution of the Al electrode. The desmutting treatment at step S13 uses a nitric acid (HNO₃) solution to remove smut generated on the Al electrode surface during the etching at step S12.

As depicted in FIG. 7, in the process at step S14, the water 21 is retained in the reservoir portion 15 (inside the recess) of each chip region 2 of the semiconductor wafer 1, thereby retaining the water 21 on the surface of the dummy electrode 12. For example, multiple semiconductor wafers 1 placed on a transport jig (e.g., the wafer cassette 31) for transporting the semiconductor wafers 1 are submerged with the wafer cassette 31 into the water 21 that fills the bath 41 (FIG. 10). The semiconductor wafers 1 are arranged at predetermined intervals with their respective peripheral edges (nonoperating regions 4) inserted into slots 32 of the wafer cassette 31. The wafer cassette 31 is immersed into the water 21 in the bath 41 so that the main surfaces (front and back surfaces) of the semiconductor wafer 1 and water surface of the water 21 in the bath 41 are perpendicular to each other.

The wafer cassette 31 is immersed into the water 21 in the bath 41, thereby filling the reservoir portions 15 of the chip regions 2 of all the semiconductor wafers 1 in the wafer cassette 31 with the water 21. From this state, the wafer cassette 31 is pulled up from the water 21 in the bath 41 in an opposite vertical direction (direction opposite to the direction in which gravity acts). At this time, water 21 is blocked by the convex portion 14 which forms a sidewall of the reservoir portion 15 on the wafer lower end side, the water remains inside the water reservoir portion 15 without flowing down from there and is held on the surface of the dummy electrode 12 (FIG. 11). Therefore, by simply immersing the wafer cassette 31 into the water 21 that fills the bath 41 and then lifting the wafer cassette 31 up, the water 21 can be retained in the reservoir portion 15 of the chip regions 2 of all the semiconductor wafers 1 in the wafer cassette 31.

A width (vertical width) w of the reservoir portion 15 and a depth (height of the convex portion 14) d of the reservoir portion 15 are appropriately set so that the water 21 remains in the reservoir portion 15 of chip regions 2 of the semiconductor wafer 1 in a state so that when the semiconductor wafer 1 is lifted up from the water 21 in the bath 41 in the opposite vertical direction (namely, a state in which the main surface of the semiconductor wafer 1 is parallel to the vertical direction), preferably, the entire surface of the dummy electrode 12 is covered with the water 21 in the reservoir portions 15 of chip regions 2. Instead of the water 21, a zincate solution (low-concentration solution) with a lower concentration than the zincate solution (liquid solution) 22 used in the process at step S15 described later may be retained in the reservoir portions 15 of chip regions 2. In this case, the bath 41 into which the semiconductor wafer 1 is immersed may be filled with the low-concentration zincate solution.

In conjunction with dissolving (etching) the Al oxide film on the surface of the front electrode 10 (main electrode 11 and dummy electrode 12) with the zincate solution 22, the zincate treatment at step S15 precipitates Zn films (metal films) 17 and 18 on the front electrode 10 surface by a substitution reaction between Al in the front electrode 10 and zinc (Zn: second metal) in the zincate solution 22. For example, multiple semiconductor wafers 1 placed on the transport jig (e.g., the wafer cassette 31) for transporting the semiconductor wafers 1 are submerged together with the wafer cassette 31 in the zincate solution 22 that fills the bath 42 (FIG. 10). The multiple semiconductor wafers 1 are arranged at the predetermined intervals with the respectively outer peripheries thereof (nonoperating regions 4) inserted into the slots 32 of the wafer cassette 31.

The water 21 is retained in the reservoir portions 15 of chip regions 2 of the semiconductor wafer 1, so that a concentration difference occurs in zincate solution 22 and 23 at the surfaces of the front electrodes 10 in chip regions 2 of the semiconductor wafer 1. That is, the zincate solution 22 is diluted by the water 21 in the reservoir portions 15 to become a zincate solution 23 having a relatively low concentration in the portions at the surface of the dummy electrodes 12 while nearly maintaining the predetermined concentration (relatively high concentration) required for the zincate treatment at step S15 in portions other than the portions at the surface of the dummy electrodes 12. While FIG. 8 depicts one chip region 2 on the front surface of the semiconductor wafer 1 being covered with the zincate solution 22, the zincate solution 22 covers the entire front surface of the semiconductor wafer 1 (see FIG. 10).

As depicted in FIG. 8, the concentration difference between the zincate solutions 22 and 23 causes a difference in solubility (electromotive force) at the surface of the front electrode 10 and a pseudo concentration cell operates in which the zincate solution 22 is set as an electrolyte, the main electrode 11 (Al electrode) and the dummy electrode 12 (Al electrode) are respectively set as an anode and cathode, and a metal element (Al) in the Al electrode and a metal ion (Zn²⁺ (cation with electrolyte)) in the zincate solution 22 exchange electrons (e⁻). Specifically, the Al in the front electrode 10 releases electrons and becomes a cation (Al³⁺) to be dissolved into the zincate solution 22, and the metal ion (Zn²⁺) in the zincate solution 22 receives the electrons to become a metal element (Zn) instead of Al and precipitates on the surface of the front electrode 10. The relatively low concentration zincate solution 23 on the surface of the dummy electrode 12 allows Al to be dissolved easily from the surface of the dummy electrode 12. That is, at the surface of the front electrode 10, in a portion constituting the surface of the dummy electrode 12, an oxidation reaction (dissolution of Al) of formula (1) is promoted. Since the zincate solution 22 has a relatively high concentration at the surface of the main electrode 11, Zn in the zincate solution 22 precipitates easily. The electrons emitted by the Al dissolution on the surface of the dummy electrode 12 move from the dummy electrode 12 to the main electrode 11 to be supplied from the surface of the main electrode 11 to the zincate solution 22. Therefore, on the surface of the main electrode 11, the reduction reaction (Zn precipitation) of formula (2) takes precedence over the oxidation reaction of formula (1), suppressing the Al dissolution on the surface of the main electrode 11.

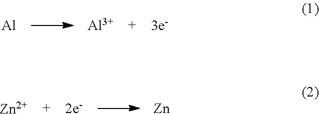

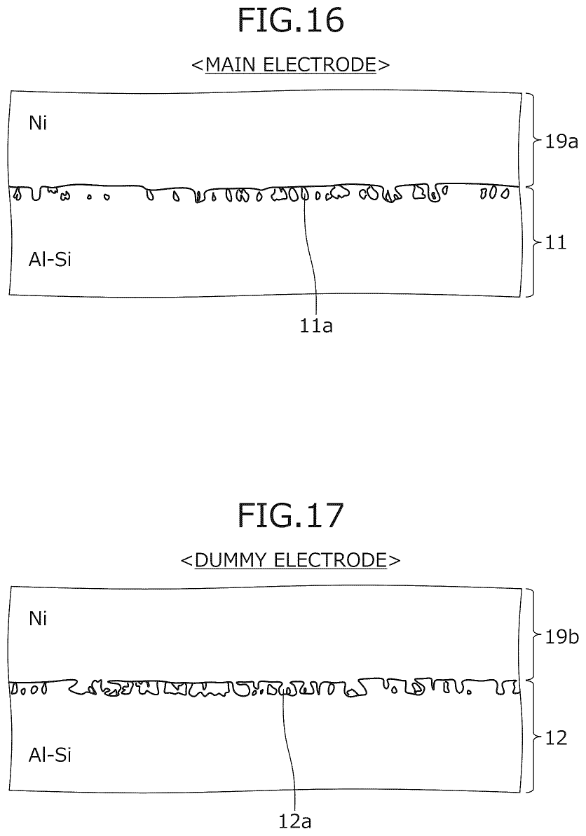

The Zn films 17 and 18 precipitate respectively on the surfaces of the main electrode 11 and the dummy electrode 12 by the reduction reaction of formula (2) (FIG. 9). By facilitating the Al dissolution on the surface of the dummy electrode 12, compared to the surface of the main electrode 11, more elongated grooves in a depth direction (e.g., grooves with a depth of about several hundred nm) called spikes 12a due to the Al dissolution are generated on the surface of the dummy electrode 12 (see FIGS. 16 and 17 described later). The larger a surface area of the dummy electrode 12 is, the more the Al dissolution on the surface of the dummy electrode 12 is facilitated, thereby improving the effect of suppressing the dissolution of the main electrode 11 (Al dissolution into the zincate solution 22). A surface state of the front electrode 10 can be detected by observing a cross section of the semiconductor chip using, for example, a focused ion beam (FIB) device.

After the zincate treatment is completed, the wafer cassette 31 is lifted from the bath 42. The zincate treatment at step S15 may be performed under existing conditions (temperature, time) using the zincate solution 22 of an existing composition. During the period from the start to the completion of the zincate treatment, preferably, the zincate solution 23 diluted with the water 21 retained in the reservoir portion 15 remains at a lower concentration than the zincate solution 22 in the bath 42. The zincate solution 22 is, for example, an alkaline plating solution obtained by dissolving such as zinc oxide (ZnO) and additives in a sodium hydroxide (NaOH) aqueous solution. The concentration of the zincate solution 22 is the mass of Zn relative to that of the NaOH aqueous solution per volume (=mass of NaOH aqueous solution [g/l (grams per liter)]/mass of Zn [g/l]), and the concentration of the zincate solution 22 increases as the mass of Zn increases.

Next, on the surface of the front electrode 10, electroless nickel (Ni: third metal) plating (step S16) and electroless Au (third metal) plating (step S17) are performed in this order, thereby completing the process at step S6. In the electroless Ni plating at step S16, the Zn films 17 and 18 are allowed to contact a plating solution containing Ni, which is less noble than Zn, and Ni plating films 19a and 19b are precipitated on the surfaces of the main electrode 11 and the dummy electrode 12, respectively, by an autocatalytic reaction (reductive plating) of Ni being substituted for Zn (see FIGS. 16 and 17). The surface of the front electrode 10 is covered with the Zn films 17 and 18, thereby improving adhesion of the Ni plating films 19a and 19b in conjunction with suppressing oxidation of the surface of the front electrode 10. The Ni plating films 19a and 19b have a function of improving adhesion with solder.

In the electroless Au plating at step S17, Ni in the Ni plating films 19a and 19b is dissolved and the Au plating film (not depicted) is precipitated on the surface of the Ni plating films 19a and 19b. In conjunction with preventing oxidation of the surface of the Ni plating films 19a and 19b, the Au plating film imparts solder wettability to the surfaces of the Ni plating films 19a and 19b. By the electroless plating at steps S16 and S17, plating films are formed on the surface of the front electrode 10, that is, the Ni plating films 19a and 19b and the Au plating film are precipitated in this order. A thickness of the Au plating film is too thin to be detected by the FIB device, for example. Therefore, collectively, a plating film combining the Ni plating films 19a, 19b and the Au plating film may be referred to as a Ni/Au plating film as depicted in FIG. 1.

The surface of the plating film on the dummy electrode 12 is roughened corresponding to surface roughness of the dummy electrode 12 (unevenness due to the spikes 12a). As described above, dissolution of the main electrode 11 is suppressed, so that the surface of the main electrode 11 is less prone to spikes 11a than the surface of the dummy electrode 12 (see FIGS. 16 and 17), and a Zn film 17 with a substantially constant thickness is precipitated on the surface of the main electrode 11. Therefore, the surface of the plating film on the main electrode 11 is flatter than that of the plating film 19b on the dummy electrode 12. The surface of the plating film on the main electrode 11 is less prone to appearance defects, in conjunction with attaining the desired adhesion between the main electrode 11 and the plating film, the surface roughness of the plating film on the main electrode 11 can be suppressed to an extent that the semiconductor chip can be automatically recognized. After the process at step S6, the dummy electrode 12 may be covered with the insulating film.

The appearance defect of the surface of the plating film is, for example, unevenness (surface roughness) that occurs at the surface of the plating film corresponding to the unevenness (spikes 11a, 12a, and the like) of the surface of the front electrode 10. When excessive diffused reflection of light occurs due to the unevenness of the surface of the plating film, there is a risk that the semiconductor chip cannot be image-recognized in the semiconductor manufacturing device. If the spikes 11a occur excessively on the surface of the main electrode 11, the sides of the multiple spikes 11a are connected to each other, whereby the adhesion between the main electrode 11 and the plating film at the connection points of the spikes 11a decreases. Since the dummy electrode 12 is not used as the semiconductor device 7, the surface of the plating film on the dummy electrode 12 may have unevenness to an extent that does not hinder the fabrication (manufacturing) of the semiconductor device 7. In a case in which the dummy electrode 12 is covered with the insulating film after the process at step S6, the surface of the plating film on the dummy electrode 12 may have appearance defects.

Next, the protective tape is peeled off from the side of the semiconductor wafer 1 and the protective tape is peeled off from the back surface of the semiconductor wafer 1, by an existing tape peeling method. A predetermined electrical test is performed on the semiconductor wafer 1 and thereafter, the semiconductor wafer 1 is diced (cut) along the scribe regions 3 thereby forming the chip regions 2 into individual chips (step S7), whereby the semiconductor device 7 (semiconductor chip) is completed. The reservoir portion 15 may remain in the product (semiconductor device 7), or the dummy electrode 12 and the reservoir portion 15 may be cut off during the process at step S7. The processes at steps S5 and S6 may also be performed on the surface of the gate pad 16.

As described above, according to the first embodiment, a dummy electrode connected to the main electrode is formed using the same material as the main electrode of the semiconductor element. During the zincate treatment, a concentration of the zincate solution on the surface of the dummy electrode is made lower than that on the surface of the main electrode, whereby a concentration cell operates with the zincate solution as an electrolyte, and the main electrode and the dummy electrode as electrodes, thereby, facilitating dissolution of the dummy electrode. Thus, the dissolution of the main electrode can be suppressed to thereby suppress the occurrence of spikes at the surface of the main electrode. A Zn film of a substantially constant thickness is precipitated on the entire surface of the main electrode, resulting in forming a plating film with high adhesion on the surface of the main electrode, whereby the reliability of the semiconductor device (semiconductor chip) can be improved.

According to the first embodiment, a convex portion made of an insulating material is formed surrounding the surface of the dummy electrode in a plan view. Water is retained in a recess (reservoir portion) surrounded by the convex portion on the surface of the dummy electrode, thereby storing water on the surface of the dummy electrode, and the semiconductor wafer is immersed in the zincate solution in this state, whereby the concentration of the zincate solution on the surface of the dummy electrode can be made lower than that on the surface of the main electrode. Since only adding a process of forming the dummy electrode, a process of forming the reservoir portion, and a process of storing water on the surface of the dummy electrode (storing water in the reservoir portion) to an existing manufacturing process is required, the adhesion between the main electrode and the plating film can be improved by a simple method.

A second embodiment is described. A method of manufacturing a semiconductor device according to the second embodiment and a surface processing method according to the second embodiment solving the above problems are described. FIGS. 12, 13, 14, and 15 are cross-sectional views schematically depicting states of the semiconductor device according to the second embodiment during manufacture. Flowcharts depicting an outline of the method of manufacturing the semiconductor device 7 according to the second embodiment and an outline of the surface processing method according to the second embodiment are the same as those depicted in FIGS. 1 and 2, respectively. A layout of the semiconductor wafer 1 during the manufacture of the semiconductor device 7 according to the second embodiment as viewed from the front surface is the same as that depicted in FIG. 3. A plan view of the chip region 2 of the semiconductor wafer 1 is one in which the reservoir portion 15 in FIGS. 4 and 5 is replaced with a hydrogel layer 51.

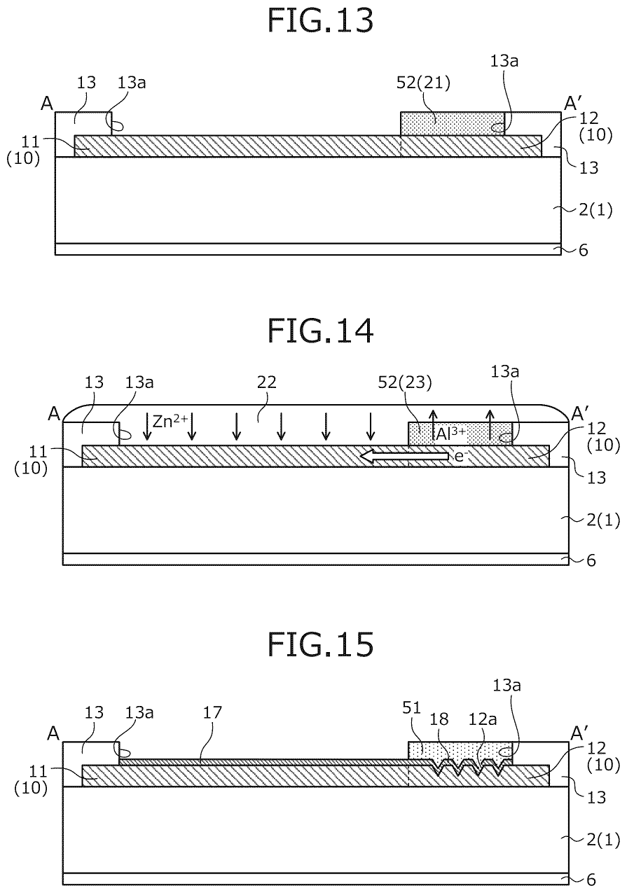

FIGS. 12, 13, 14, and 15 are cross-sectional views taken along line A-A′ in FIGS. 4 and 5. FIG. 12 depicts a state after the process at step S2 in FIG. 1. FIG. 13 depicts a state after the process at step S14 in FIG. 2. FIGS. 14 and 15 depict states during and after the process at step S15 in FIG. 2, respectively. A state in which the semiconductor wafer 1 is immersed in a bath filled with a predetermined liquid (bath 41 filled with water 21 in the process at step S14, bath 42 filled with zincate solution 22 in the process at step S15) during the processes at steps S14 and S15 of the surface processing method according to the second embodiment is the same as that depicted in FIG. 10.

The method of manufacturing the semiconductor device according to the second embodiment and the surface processing method according to the second embodiment are different from the method of manufacturing the semiconductor device according to the first embodiment and the surface processing method according to the first embodiment in that the hydrogel layer 51 is formed on the surface of the dummy electrode 12 as the reservoir portion 15 for retaining the water 21. For example, in the second embodiment, first, structures of the front surface of the semiconductor device 7 are formed on the surface of the dummy electrode 12 in the same manner as in the first embodiment (step S1: see FIG. 1). Then, as depicted in FIG. 12, the hydrogel layer 51 is formed as the reservoir portion for retaining the water 21 during the process at step S6 described later (step S2: see FIG. 1).

The hydrogel layer 51 is an insulating layer formed by gelling a polymer material and has a structure for absorbing and retaining liquids. The hydrogel layer 51 has a function of retaining the water 21 on the surface of the dummy electrode 12 during the process at step S14 described later (see FIGS. 2 and 13). The hydrogel layer 51 may be formed before the process at step S14 (preferably before the process at step S6). Next, similar to the first embodiment, the processes from step S3 (back grinding) to step S5 (ashing treatment) (see FIG. 1), and the processes from step S11 (degreasing treatment) to step S13 (desmutting treatment) of step S6 (see FIGS. 1 and 2) are performed in this order.

Next, in the process at step S14 (see FIG. 2), similar to the first embodiment, the wafer cassette 31 (see FIG. 10) in which the multiple semiconductor wafers 1 are placed is immersed in the water 21 in the bath 41 and then is pulled up. Hence, as depicted in FIG. 13, the hydrogel layer 51 on the dummy electrodes 12 of chip regions 2 of the semiconductor wafers 1 absorb the water 21 and the water 21 is held on the surface of the dummy electrode 12 by a hydrogel layer 52 filled with the water 21. Then, similar to the first embodiment, the wafer cassette 31 (see FIG. 10) in which the multiple semiconductor wafers 1 are placed is immersed in the zincate solution 22 that fills the bath 42, and the zincate treatment (see FIG. 2) at step S15 is performed.

Similar to the first embodiment, the hydrogel layer 52 filled with the water 21 causes a concentration difference between the zincate solutions 22 and 23 at the surfaces of the front electrodes 10 in chip regions 2 of the semiconductor wafer 1. That is, the zincate solution 22 absorbed in the hydrogel layer 52 is diluted by the water 21 and the hydrogel layer 52, which contains the zincate solution 23 at a lower concentration than the zincate solution 22 in the bath 42, is arranged on the surface of the dummy electrode 12. While FIG. 14 depicts one chip region 2 on the front surface of the semiconductor wafer 1 being covered with the zincate solution 22, the zincate solution 22 covers the entire front surface of the semiconductor wafer 1 (see FIG. 10).

Therefore, as depicted in FIG. 14, the relatively low concentration zincate solution 23 contained in the hydrogel layer 52 on the surface of the dummy electrode 12 facilitates the Al dissolution on the surface of the dummy electrode 12, similar to the first embodiment. The Al dissolution on the surface of the main electrode 11 is suppressed. Therefore, as depicted in FIG. 15, similar to the first embodiment, more spikes 12a are generated at the surface of the dummy electrode 12 than at the surface of the main electrode 11. Similar to the first embodiment, the Zn films 17 and 18 are precipitated on the surfaces of the main electrode 11 and the dummy electrode 12 by the zincate treatment at step S15.

Thereafter, similar the first embodiment, the processes from step S16 and thereafter (see FIGS. 1 and 2) are performed in the order depicted, whereby the semiconductor device 7 (semiconductor chip) is completed similar to the first embodiment. During the electroless plating at steps S16 and S17, the hydrogel layer 51 absorbs the plating solution, thereby forming the plating film similar to the first embodiment. In any of the washing and drying performed after the process at step S15, the hydrogel layer 51 is washed and dried to become liquid-free. This liquid-free hydrogel layer 51 may remain on the product (semiconductor device 7) or may be peeled off at any timing after the zincate treatment at step S15.

As described above, according to the second embodiment, even when a reservoir portion made of hydrogel layers is formed on the surface of the dummy electrode, water can be retained on the surface of the dummy electrode, so that the concentration of the zincate solution of the dummy electrode can be made lower than the concentration of the zincate solution on the surface of the main electrode during the zincate treatment, and an effect similar to that of the first embodiment can be obtained.

A verification example is described. According to the method of manufacturing the semiconductor device according to the first embodiment and the surface processing method according to the first embodiment (see FIGS. 1, 2, 6 to 9) described above, the Ni plating films 19a and 19b were formed on the surface of the front electrode 10 and states of the main electrode 11 and the dummy electrode 12 were detected by the FIB device, the results thereof are depicted in FIGS. 16 and 17, respectively. FIGS. 16 and 17 are cross-sectional views depicting the results of observing the states of the surfaces of the front electrodes in the verification example. The front electrode 10 (main electrode 11 and dummy electrode 12) was an Al—Si electrode.

As depicted in FIGS. 16 and 17, while the spikes 11a and 12a were generated at both the surface of the main electrode 11 and the surface of the dummy electrode 12 due to the Al elution during the zincate treatment at step S15, more spikes 12a were confirmed to occur at the surface of the dummy electrode 12 than at the surface of the main electrode 11. Therefore, performing the zincate treatment at step S15 while the water 21 is held on the surface of the dummy electrode 12 by the reservoir portion 15 of the first embodiment was confirmed to facilitate dissolution of the dummy electrode 12 and thereby suppress dissolution of the main electrode 11.

The reservoir portion (hydrogel layer 51) of the second embodiment can also hold the water 21 on the surface of the dummy electrode 12 similar to the reservoir portion 15 of the first embodiment and thus, results similar to those depicted in FIGS. 16 and 17 are assumed to be obtained.

In the foregoing, the present disclosure is not limited to the described embodiments and various modifications not departing from the spirit of the present disclosure are possible. For example, in the described embodiments, while a zincate treatment (surface processing) that uses an Al electrode (front electrode) as a base (material to be plated) is described, without limitation hereto, the present disclosure is applicable to surface processing involving dissolution of a metal layer (material to be plated) by a solution (acid solution or alkaline solution), in this case, with the solution as an electrolyte, and the metal layer as the main electrode and dummy electrode of the present disclosure operating as a pseudo concentration cell, effects similar to those described in the present disclosure are obtained.

That is, the material to be plated may be mainly composed of a first metal (Al in the present disclosure) less noble (has a higher ionization tendency) than a second metal (Zn in the zincate solution in the present disclosure) in a solution (zincate solution, acid solution or alkaline solution). A plating film formed on the surface of the material to be plated is not limited to an Ni/Au plating film and may be a plating film containing a third metal and precipitated by displacement plating (electroless plating) utilizing a difference in the ionization tendencies between the second metal and the third metal, the third metal being more noble (having a lower ionization tendency) than the second metal.

The surface processing method and the method of manufacturing a semiconductor device according to the present disclosure achieve an effect in that reliability is improved.

As described above, the semiconductor device and the method of manufacturing the semiconductor device according to the present disclosure are useful for semiconductor devices in which bonding wires are bonded to surface electrodes via plating films, and are particularly suitable for forming Ni plating films on the surfaces of Al electrodes by electroless plating.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A surface processing method for forming a plating film on a surface of a metal layer in manufacturing a semiconductor device, the metal layer containing a first metal, the method comprising:
as a first precipitation process, immersing the metal layer in a first solution containing a second metal that is more noble than the first metal, to thereby precipitate a metal film containing the second metal on the surface of the metal layer; and
as a second precipitation process, performing an electroless plating treatment using a second solution, to replace the second metal in the metal film with a third metal contained in the second solution and to precipitate the plating film containing the third metal on the surface of the metal layer, wherein
the metal layer includes a first portion and a second portion mutually exclusive of each other, and
in the first precipitation process, a concentration of the first solution is lower at a surface of the second portion than at a surface of the first portion.

2. The surface processing method according to claim 1, comprising:
retaining a liquid on the surface of the second portion of the metal layer before the first precipitation process, the liquid being water or a third solution having a lower concentration of the second metal than the first solution, wherein
the first precipitation process includes diluting the first solution at the surface of the second portion of the metal layer with the liquid.

3. The surface processing method according to claim 2, wherein
the retaining includes:
forming, on the surface of the metal layer, a convex portion containing an insulating material to surround the surface of the second portion in a plan view of the metal layer, to thereby form a recess on the surface of the second portion, and
retaining the liquid in the recess to thereby retain the liquid on the surface of the second portion of the metal layer.

4. The surface processing method according to claim 2, wherein
the retaining includes forming, on the surface of the metal layer, a hydrogel layer covering the surface of the second portion, the hydrogel layer being configured to absorb the liquid, to thereby retain the liquid on the surface of the second portion of the metal layer.

5. The surface processing method according to claim 1, wherein
the first metal is aluminum,
the first solution is a zincate solution containing zinc as the second metal, and
the third metal is nickel.

6. A method of manufacturing a semiconductor device having a metal layer whose surface is covered with a plating film formed by the surface processing method according to claim 1, the method comprising:
before the first precipitation process,
preparing a semiconductor substate having a main surface;
forming an element structure in the semiconductor substrate, at the main surface of the semiconductor substrate; and
forming the metal layer on the main surface, the first portion of the metal layer constituting a main electrode of the semiconductor device and being electrically connected to the element structure, and the second portion of the metal layer constituting a dummy electrode of the semiconductor device.
